(19) United States
(12) Patent Application Publication
(10) Pub. No.: US 2003/0085129 A1
(43) Pub. Date: May 8, 2003

(54) Method of forming zinc oxide film, method of producing semiconductor element substrate using same, and method of producing photovoltaic element

(76) Inventor: Yukie Shishido, Nara (JP)

Correspondence Address: FITZPATRICK CELLA HARPER & SCINTO, 30 ROCKEFELLER PLAZA, NEW YORK, NY, 10112, US

(21) Appl. No.: 10/187,810

(22) Filed: Jul. 3, 2002

(30) Foreign Application Priority Data
Jul. 4, 2001 (JP) 202950/2001 (PAT)

(51) Int. Cl. C25D 7/06; H01L 21/31; H01L 21/469; C23C 16/00; C25D 9/00

(52) U.S. Cl. 205/155; 205/333; 427/255.19

(57) ABSTRACT

A ZnO film forming method is a method of letting an electric current flow between a conductive substrate immersed in at least one forming bath containing at least zinc ions, and a counter electrode immersed in the at least one forming bath, thereby forming a zinc oxide film on the conductive substrate, wherein deposition of a zinc oxide film on a back surface of the conductive substrate is decreased by adjusting (1) a distance between the back surface of the conductive substrate and a region facing at least the periphery of the back surface in a surface facing the back surface, and (2) an electric conductivity of the forming bath, and (3) an electric current density between the conductive substrate and the counter electrode, thereby establishing a mass production technology based on electrolytic deposition of the zinc oxide film as a low cost technology and providing the method of forming the ZnO film with high performance and excellent adhesion to the substrate while reducing the amount of the film deposited on the back surface.

### BACKGROUND OF THE INVENTION

1. Field of the Invention

The present invention relates to a method of forming a zinc oxide film, a method of producing a semiconductor element substrate using the forming method, and a method of producing a photovoltaic element and, more particularly, to a technology of forming a zinc oxide film in good condition only on one side of a substrate.

2. Related Background Art

Conventionally, a reflecting layer on a back surface (which is a surface on the side opposite to the light incidence side of a semiconductor layer) has been utilized in order to improve the absorption efficiency at long wavelengths of the photovoltaic element using a semiconductor layer of hydrogenated amorphous silicon, hydrogenated amorphous silicon germanium, hydrogenated amorphous silicon carbide, microcrystalline silicon, polycrystalline silicon, or the like.

It is desired that the reflecting layer demonstrate effective reflection characteristics at wavelengths near the band edge of the semiconductor materials where absorption thereof becomes lower, i.e., in the wavelength range from 800 nm to 1200 nm. This condition is adequately met by metal layers made of such materials as gold, silver, copper, and aluminum.

It is also conventional practice to provide an uneven layer optically transparent in a predetermined wavelength range, in order to effect optical confinement. The uneven layer is usually provided between the metal layer and the semiconductor layer to improve the short-circuit current density Jsc through effective use of the reflecting layer. Further, in order to prevent degradation of characteristics due to shunt paths, there is a conventional method of providing a layer of a transparent material with electrical conduction, i.e., a transparent conductive layer between the metal layer and the semiconductor layer. Extremely generally speaking, these layers are deposited by such methods as vacuum evaporation and sputtering, and achieve the improvement in the short-circuit current density Jsc of not less than 1 mA/cm².

Studies on the reflectance and texture structure of the reflecting layer comprised of silver atoms are described, for example, in “29p-MF-22: Optical confinement effect in a-SiGe solar cell on stainless steel substrate”, Extended Abstracts (The 51st Autumn Meeting, 1990); The Japan Society of Applied Physics, p747, or in “P-IA-15 a-SiC/a-Si/a-SiGe Multi-Bandgap Stacked Solar Cells With Bandgap Profiling”, Sannomiya et al., Technical Digest of the International PVSEC-5, Kyoto, Japan, p381, 1990. It is described in these examples that effective unevenness was formed in the reflecting layer by deposition of two layers of silver at different substrate temperatures and that the increase of short-circuit current by the optical confinement effect was achieved by combination with a zinc oxide layer formed thereon.

The transparent layer used as the optical confinement layer in these examples is deposited by resistance heating or electron beam evaporation, sputtering, ion plating, CVD, or the like, and they involve the problems that a vacuum chamber is expensive, production cost of target materials and others is high, the efficiency of utilization of materials is not high, and so on, which extremely increase the production cost of the photovoltaic element using these techniques. This was great hindrance to industrial application of solar cells.

A zinc oxide forming technique by a liquid phase deposition process was reported as a solution to such problems (“Preparation of ZnO film by electrolysis of aqueous solution”, Extended Abstracts (The 65th Autumn Meeting, 1995); The Japan Society of Applied Physics, p410).

Japanese Patent Application Laid-Open No. 10-195693 suggests a method of forming the zinc oxide film by electrolytic deposition (or electrodeposition). Specifically, it discloses a technique of letting an electric current flow between a conductive substrate immersed in an aqueous solution containing at least nitrate ions, zinc ions, and a carbohydrate, and an electrode immersed in the solution, thereby forming the zinc oxide film on the conductive substrate.

Further, Japanese Patent Application Laid-Open No. 10-140373 suggests a method of forming the zinc oxide film by electrolytic deposition so as to produce the uniform film with and excellent adhesion to the substrate. Specifically, it discloses the method of producing the zinc oxide film, which comprises the step of forming a first zinc oxide film on a substrate by sputtering, and the step of immersing the substrate in an aqueous solution containing at least nitrate ions, zinc ions, and a carbohydrate, and letting an electric current flow between the substrate and an electrode immersed in the solution, thereby forming a second zinc oxide film on the first zinc oxide film.

These methods eliminate the need for the expensive vacuum chamber and targets, and are thus able to drastically decrease the production cost of zinc oxide (ZnO). Since they can also be applied to deposition on a large-area substrate, they are promising for large-area photovoltaic elements like solar cells. However, the methods of electrochemically depositing ZnO still have problems to be solved.

Namely, during formation of the ZnO film by electrolytic deposition, when a conductive substrate is used as the substrate, the zinc oxide film is not deposited only on a film-forming surface (i.e., a front surface) of the substrate, but is also deposited to a certain extent on a non-film-forming surface (i.e., a back surface). The zinc oxide film deposited on the back surface of the substrate (hereinafter referred to as “back surface film”) might be a film alien to the zinc oxide film deposited on the front surface of the substrate because of the difference in deposition conditions (mainly because of the difference in the way of application of the electric field, and the like). Specifically, it might be a fragile film of low density different in surface unevenness shape and mechanical strength. If this back surface film exists over a certain level, there will arise the following problems, for example, in formation of the semiconductor element such as the solar cell or the like.

(1) When the substrate with the zinc oxide film formed by electrolytic deposition is supplied to the production step of photovoltaic element, degassing in the vacuum chamber might cause degradation of characteristics of the solar cell. Particularly, the back surface film tends to have a low density and a large surface area and thus increases the risk of carrying oxygen, nitrogen, water, and other adsorbing gas into the vacuum chamber.

(2) During conveyance of the substrate in the vacuum chamber, the back surface film might be peeled off to become dust and contaminate the interior of the vacuum chamber.

(3) When the roll to roll system is employed, the back surface film is also wound up simultaneously in a winding step and can be peeled off during the winding to fall as contaminant particles to between substrate windings. In this case, there is the risk of contact of the contaminant particles with the zinc oxide film deposited on the front surface to damage the film.

(4) The existence of the back surface film can result in variation of friction coefficient to induce weaving and unsuccessful conveyance.

(5) When, after the formation of the zinc oxide film, soldering, adhesive coating, or the like as post-processing is performed on the back surface, the deposition of the film on the back surface of the substrate might cause degradation of workability, e.g., welding failure, degradation of adhesion, and so on.

On the other hand, Japanese Patent Application Laid-Open No. 11-286799 discloses a method of electrolytically etching the zinc oxide film deposited on the back surface, using an electrode for preventing the deposition of the back surface film. This method can greatly improve the deposition of the film on the back surface. In the case where the metal film of silver or the like reactive with an oxidizing liquid is placed between the substrate and the zinc oxide film, for example, however, if a stronger electric field is applied in order to increase the deposition rates over the conventional level, the electrochemical reaction will not occur only on the zinc oxide film deposited on the back surface but also occur on the zinc oxide film deposited on the front surface and further up to the metal film, possibly posing problems of discoloration, dissolution, and so on.

Japanese Patent Application Laid-Open No. 10-259496 suggests a technique of preventing the zinc oxide film from being deposited on the back surface of the substrate during the formation of the zinc oxide film by electrolytic deposition. Specifically, it discloses the technique of preventing the unwanted zinc oxide film from being deposited on the back surface of the substrate, by providing a rotary belt for conveying the substrate while covering one surface of the long conductive substrate immersed in an aqueous solution containing nitrate ions and zinc ions.

This method can effectively suppress the deposition of the back surface film, but requires a member for covering the back surface of the substrate, which might complicate the structure of the apparatus and also increase the cost.

These zinc oxide film forming methods by electrolytic deposition have another problem that, particularly, with increase in the current density or increase in the concentration of the forming bath, there can readily occur abnormal growth in acicular, spherical, or dendritic shape over the micrometer order on the deposited film on the front surface. When this thin film of zinc oxide is used as part of the photovoltaic element, these abnormally grown portions can possibly be the cause of inducing shunt paths of the photovoltaic element.

### SUMMARY OF THE INVENTION

An object of the present invention is to solve the above problems to establish a mass production technology of the zinc oxide film by electrolytic deposition as a low cost technology, thereby providing a method of forming the zinc oxide film with high performance and with excellent adhesion to the substrate while reducing the amount of the film deposited on the back surface. Furthermore, the present invention also provides the photovoltaic element with high quality and of low power cost by applying the method of forming the zinc oxide film.

In order to achieve the above object, the inventor has conducted elaborate research on the method of reducing the deposition of film on the back surface, which occurred during the formation of the zinc oxide film on the conductive substrate, and obtained the knowledges described below.

Namely, the principal cause of forming the zinc oxide film on the back surface of the substrate is influence of electric flux lines existing in the forming bath, and the electric flux lines going round to the back surface induce electrochemical reaction on the conductive substrate to form the zinc oxide film thereon.

The following will further describe the details of the formation of the back surface film due to the electric flux lines going round to the back surface of the substrate, and a method of reducing the formation of the back surface film.

The zinc oxide film by electrolytic deposition is formed by letting an electric current flow between a working electrode of the conductive substrate and a counter electrode. The main reaction takes place on the front surface of the working electrode facing the counter electrode, while the reaction also takes place on the back surface of the working electrode because of the rounding of the electric flux lines in the forming bath to form the zinc oxide film thereon. Since the electric flux lines going round to the back surface are different from those on the front surface, the zinc oxide film formed on the back surface is different in structure and characteristics from the film formed on the front surface. If the conductive substrate with such zinc oxide films thereon is applied as a substrate for the semiconductor element or the photovoltaic element, it will bring the negative effect as described previously.

The inventor contemplated that an effective means was to limit the electric flux lines going round to the back surface, and conducted further research.

Specifically, the inventor studied the countermeasures from the following two viewpoints:

(1) to decrease the rounding of the electric field spatially;

(2) to control the influence of the electric field.

Then, the inventor arrived at the conclusion that by adjustment of (1) the distance between the back surface of the conductive substrate and a region facing at least the periphery of the back surface in a surface facing the back surface; and (2) the electrical conductivity of the forming bath; and (3) the electric current density between the conductive substrate and the counter electrode, it became feasible to decrease the space where electric flux lines went around to the back surface of the substrate and to control the electric field of the forming bath itself in a state in which reactivity was ensured, thereby enabling effective reduction of deposition of the back surface film.

The present invention has been accomplished on the basis of these knowledges, and has the following configuration.

Namely, the present invention provides a method of forming a zinc oxide film on a conductive substrate while letting an electric current flow between the conductive substrate immersed in at least one forming bath containing at least zinc ions, and a counter electrode immersed in the at least one forming bath, wherein deposition of a zinc oxide film on a back surface of the conductive substrate is reduced by adjusting (1) a distance between the back surface of the conductive substrate, and a region facing at least the periphery of the back surface in a surface facing the back surface; and (2) an electric conductivity of the forming bath; and (3) an electric current density between the conductive substrate and the counter electrode. In the present invention, the surface facing the back surface of the conductive substrate refers to a front surface of another substance in contact with the forming bath and surface existing opposite to the back surface of the conductive substrate. More specifically, it is a surface of another member existing opposite to the back surface of the conductive substrate, or a water surface of the forming bath; for example, it can be a surface of an inner wall of a tank accommodating the forming bath, a partition board disposed in the forming bath, a surface of a jig for the conductive substrate, a water surface of the forming bath accommodated in the tank, and so on. The region facing at least the periphery of the back surface in the surface facing the back surface of the conductive substrate refers to a region existing opposite to, particularly, to the periphery of the back surface, out of the surface facing the back surface of the conductive substrate.

The forming method of the zinc oxide film according to the present invention decreases the influence of the electric field going round to the back surface of the conductive substrate and thus decreases the deposition of the zinc oxide film on the back surface of the substrate. This enables the conductive substrate with the zinc oxide film formed according to the present invention to be applied to production of the photovoltaic element, which permits efficient production of a high-performance element substrate without the degradation of characteristics of the solar cell due to the degassing in the vacuum chamber and the mixing of impurities.

In the present invention, in order to further decrease the rounding space of electric flux lines to the back surface of the substrate, it is preferable that the distance between the back surface of the conductive substrate and the surface facing the back surface be controlled in a specific range throughout the entire facing region, rather than the configuration wherein only the distance between the back surface of the conductive substrate and the region facing the periphery of the back surface in the surface facing the back surface is controlled in the specific range. In the following description, a substrate back surface facing distance will denote both of the distance between the back surface of the conductive substrate and the region facing the periphery of the back surface in the surface facing the back surface and the distance between the back surface of the conductive substrate and the surface facing the back surface in the entire facing region.

In the present invention, preferably, the substrate back surface facing distance is not more than 30 mm, the electric conductivity of the forming bath is not less than 10 mS/cm nor more than 100 mS/cm, and an absolute value of the electric current density is not less than 0.1 mA/cm² nor more than 100 mA/cm². This facilitates establishment of the electric field in the solution enough to form the zinc oxide film and the decrease of the deposition of the zinc oxide film on the back surface. The substrate back surface facing distance is preferably not more than 30 mm in order to facilitate achievement of the effect of the present invention, more preferably not more than 20 mm in order to enhance the effect of reducing the rounding of electric flux lines, and still more preferably not more than 15 mm as an optimal level. There are no specific restrictions on the lower limit of the substrate back surface facing distance, but the substrate back surface facing distance is preferably short (e.g., approximately 5 mm) in a non-contact state of the back surface of the substrate with the facing surface, because contact of the back surface of the substrate with the facing surface can negatively affect the film formation of the zinc oxide film. The electrical conductivity is preferably not less than 10 mS/cm nor more than 100 mS/cm in order to facilitate achievement of the effect of the present invention and more preferably not less than 50 mS/cm in consideration of reactivity. If the electrical conductivity is too high the reactivity will also become high in the forming bath and the high reactivity will make it difficult to control the rounding of electric flux lines to the back surface at edges. Further, it will result in readily bringing about abnormal growth in acicular, spherical, or dendritic shape over the micrometer order on the deposited film on the front surface as described previously. For this reason, the upper limit of the electric conductivity is more preferably not more than 100 mS/cm. The electric current density is preferably not less than 0.1 mA/cm² nor more than 100 mA/cm² in order to facilitate achievement of the effect of the present invention, more preferably not less than 1 mA/cm² nor more than 30 mA/cm² in consideration of the reactivity and the shape of the film formed on the front surface, as in the case of the electric conductivity, and still more preferably not less than 3 mA/cm² nor more than 15 mA/cm².

In the forming method of the zinc oxide film according to the present invention, the entire surface facing the back surface of the conductive substrate is preferably made of a dielectric. This decreases the electric field going round to the back surface of the conductive substrate through the surface facing the back surface of the conductive substrate and, in turn, decreases the deposition of the zinc oxide film on the back surface of the substrate.

The forming bath containing at least zinc ions preferably contains nitrate ions and further contains a saccharide. This drastically suppresses the abnormal growth occurring on the zinc oxide film and facilitates the film formation in high concentrations, thereby permitting the formation of the zinc oxide film of preferred texture structure as an optical confinement layer. Further, it increases the yield of the photovoltaic element and permits stable continuous supply of the photovoltaic element with excellent adhesion and high performance (improvement in the short-circuit current and conversion efficiency). The saccharide included is preferably saccharose or dextrin.

The conductive substrate is also preferably a conductive substrate on which a metal film or a metal compound film is preliminarily deposited. By using the conductive substrate with the metal film or the metal compound film preliminarily deposited, the adhesion is enhanced between the substrate and the zinc oxide film deposited electrochemically. Further, when a zinc oxide film is preliminarily deposited as the metal compound film, it is feasible to efficiently and uniformly form the zinc oxide film with less abnormal growth relatively easily. A method of preliminarily depositing the metal film or the metal oxide film is desirably a sputtering method or a vacuum evaporation method.

The zinc oxide film is preferably continuously formed by a roll to roll system. When the zinc oxide film is continuously formed under conveyance of the substrate in this way, the film formation can be performed over a large area.

The present invention also provides a method of producing a semiconductor element substrate having a zinc oxide film on a conductive substrate, which comprises the step of forming the zinc oxide film by the aforementioned forming method of the zinc oxide film according to the present invention.

The present invention further provides a method of producing a photovoltaic element, which comprises the step of forming a semiconductor layer on the semiconductor element substrate produced by the aforementioned producing method of the semiconductor element substrate according to the present invention.

When the forming method of the zinc oxide film of the present invention is applied to the producing method of the semiconductor element substrate or the photovoltaic element, it is feasible to produce the photovoltaic element with high quality (excellent optimal operating current, conversion efficiency, and adhesion) and of low power cost. Further, the use of the roll to roll system permits continuous production and, particularly, permits great reduction in the production cost of the zinc oxide film, as compared with the sputtering method.

### BRIEF DESCRIPTION OF THE DRAWINGS

FIG. 1 is a schematic sectional view of an example of the photovoltaic element to which the forming method of the zinc oxide film according to the present invention can be suitably applied;

FIG. 2 is a schematic representation illustrating a zinc oxide film forming apparatus used in an example of the present invention; and

FIG. 3 is a schematic representation illustrating a zinc oxide film forming apparatus used in another example of the present invention.

### DESCRIPTION OF THE PREFERRED EMBODIMENTS

Embodiments of the present invention will be described below with reference to the drawings.

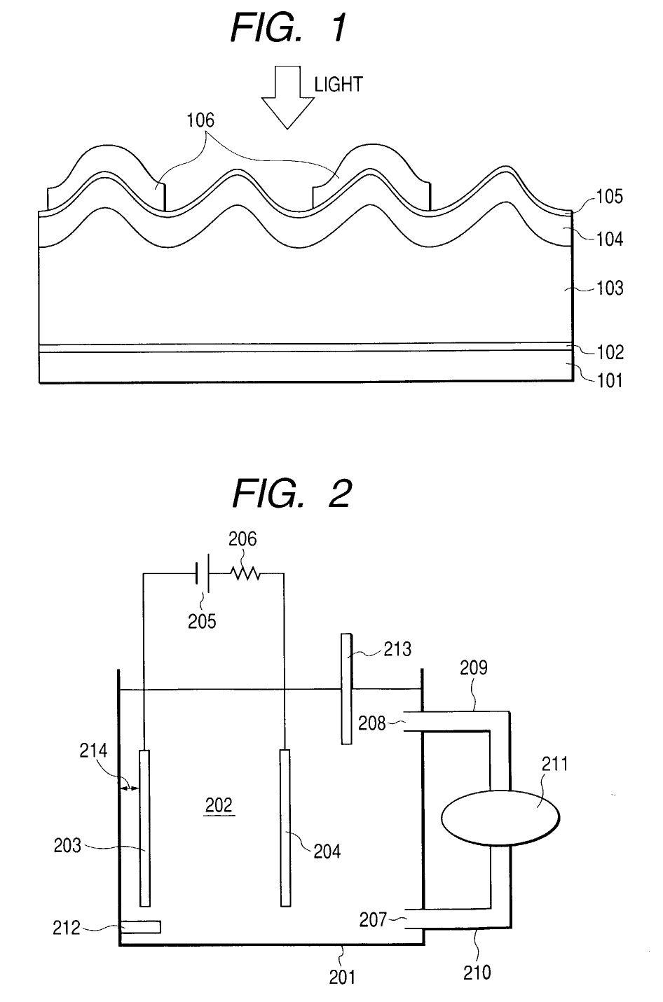

FIG. 1 is a schematic sectional view of an example of the photovoltaic element to which the forming method of the zinc oxide film according to the present invention can be suitably applied. In the drawing reference numeral 101 designates a support (substrate), 102 a metal layer, 103 a zinc oxide layer of hexagonal polycrystals, 104 a semiconductor layer, 105 a transparent conductive layer, and 106 collecting electrodes. The support (substrate) 101 and the metal layer 102 constitute an electrically conductive substrate (light-reflecting metal substrate) in the present invention. In the case where the element is constructed in structure in which light is incident from the transparent substrate side, the layers except for the substrate are formed in the reverse order.

The following will describe the components of the photovoltaic element and a production method thereof.

(Support (Substrate))

The support (substrate) 101 is a resin, glass, ceramic, or other material coated with a metal layer or a conductive material. The support 101 may have fine unevenness in its surface. The support may be formed as a transparent substrate to receive light from the substrate side.

The support can be shaped in such a long form as to adapt to continuous film formation. Particularly, stainless steel, polyimide, or the like is suitable as a material for the support, because they are flexible.

(Metal Layer)

The metal layer 102 serves as an electrode and also as a reflecting layer for reflecting light coming to the substrate 101 and making it reused in the semiconductor layer 104. A film of gold, silver, copper, aluminum, one of their respective compounds, or the like is formed by evaporation, sputtering, electrolytic deposition, printing, or the like, thereby forming the metal layer 102.

The metal layer 102 has unevenness in its surface whereby it can lengthen optical path lengths of reflected light in the semiconductor layer 104, so as to increase the short-circuit current.

When the substrate 101 itself is electrically conductive, the metal layer 102 does not always have to be formed. In this case, the substrate 101 refers to the conductive substrate in the present invention.

(Zinc Oxide Layer)

The zinc oxide layer (transparent conductive layer) 103 functions to increase diffuse reflection of incident light and reflected light, so as to lengthen optical path lengths in the semiconductor layer 104. It also functions to prevent atoms or ions in the metal layer 102 from diffusing or migrating into the semiconductor layer 104 to cause a shunt of the photovoltaic element. Further, when the zinc oxide layer 103 has some adequate resistance, it is feasible to prevent a short due to defects such as pinholes or the like of the semiconductor layer 104. The zinc oxide layer 103 desirably has unevenness in its surface as the metal layer 102 does.

In the present invention, the zinc oxide layer 103 is formed by an electrolytic deposition method described below, which is relatively low in equipment cost and material cost.

(Method of Forming Zinc Oxide Layer by Electrolytic Deposition)

The zinc oxide layer can be formed, for example, using the zinc oxide film forming apparatus shown in FIG. 2. In the formation of the zinc oxide layer by electrolytic deposition, the zinc oxide layer is preferably formed on a zinc oxide film preliminarily formed, as described in aforementioned Japanese Patent Application Laid-Open No. 10-140373, in order to enhance the adhesion to the substrate.

In the drawing numeral 201 designates a zinc oxide layer forming tank and a forming bath containing zinc ions is used as a zinc oxide layer forming bath 202. The concentration of zinc ions is preferably 0.002 mol/l to 3.0 mol/l, more preferably 0.01 mol/1 to 1.5 mol/l, and still more preferably 0.05 mol/l to 0.7 mol/l.

The forming bath 202 preferably contains nitrate ions, zinc ions, and, saccharose or dextrin. In that case the concentration of nitrate ions is preferably 0.004 mol/l to 6.0 mol/l, more preferably 0.01 mol/l to 1.5 mol/l, and still more preferably 0.1 mol/l to 1.4 mol/l. The concentration of saccharose is preferably 1 g/l to 500 g/l and more preferably 3 g/l to 100 g/l, and the concentration of dextrin is preferably 0.01 g/l to 10 g/l and more preferably 0.025 g/l to 1 g/l. In this manner, the zinc oxide film of preferred texture structure can be efficiently formed as an optical confinement layer.

The conductive substrate 203 and the zinc plate (counter electrode) 204 are electrodes, and the zinc oxide film can be formed on the both electrodes by electrolytic deposition. However, the zinc oxide film is formed on the conductive substrate 203 herein. The conductive substrate 203 and the counter electrode 204 are connected via a load resistor 206 to a power supply 205 and are arranged so as to let an approximately constant electric current flow. The counter electrode 204 can be constructed of a plurality of electrodes as occasion may demand.

In the drawing numeral 212 denotes a heater, and 213 a thermometer. When the temperature of the solution is set at or above 50° C., a uniform zinc oxide film with less abnormal growth can be efficiently formed. In order to agitate the entire solution, the apparatus is equipped with a solution circulating system consisting of a solution inlet 208, a solution outlet 207, a solution circulating pump 211, an incoming solution pipe 209, and an outgoing solution pipe 210. For small-scale apparatus, a magnetic stirrer can be used instead of the solution circulating system.

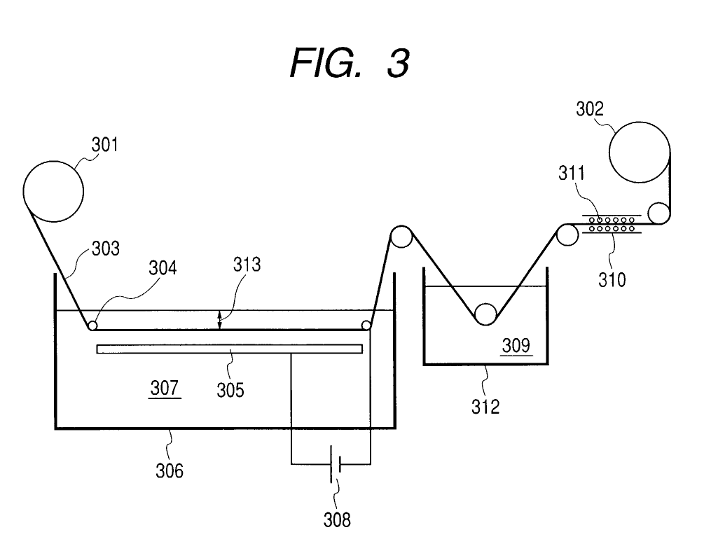

In the present invention, preferably, the substrate back surface facing distance (e.g., numeral 214 in FIG. 2 or numeral 313 in FIG. 3) is set to not more than 30 mm; the electric conductivity of the zinc oxide layer forming bath 202 to not less than 10 mS/cm nor more than 100 mS/cm; and the absolute value of the electric current density between the conductive substrate 203 and the counter electrode 204 to not less than 0.1 mA/cm² nor more than 100 mA/cm².

The substrate back surface facing distance is preferably not more than 30 mm in order to facilitate the achievement of the effect of the present invention, and is more preferably not more than 20 mm and still more preferably not more than 15 mm in order to enhance the effect of reducing the rounding of electric flux lines. There are no specific restrictions on the lower limit of the distance, but contact of the back surface of the substrate with the facing surface can negatively affect the film formation of the zinc oxide film. Therefore, it is preferable that the back surface of the substrate and the facing surface be not in contact with each other and that the substrate back surface facing distance be short (e.g., about 5 mm).

The electric conductivity of the zinc oxide layer forming bath 202 is preferably not less than 10 mS/cm nor more than 100 mS/cm in order to facilitate the achievement of the effect of the present invention and more preferably not less than 50 mS/cm in view of the reactivity. Since the reactivity of the forming bath becomes higher with increase in the conductivity, it becomes harder to control the rounding to the back surface at edges. Further, the high reactivity is apt to result in bringing about the abnormal growth in acicular, spherical, or dendritic shape over the micrometer order on the deposited film on the front surface, as described previously. For this reason, the upper limit of the conductivity is more preferably not more than 100 mS/cm.

The absolute value of the electric current density between the conductive substrate 203 and the counter electrode 204 is preferably not less than 0.1 mA/cm² nor more than 100 mA/cm² in order to facilitate the achievement of the effect of the present invention, and is more preferably not less than 1 mA/cm² nor more than 30 mA/cm² and still more preferably not less than 3 mA/cm² nor more than 15 mA/cm² in view of the reactivity and the shape of the film formed on the front surface, as in the case of the electric conductivity.

(Semiconductor Layer)

Materials suitable for the semiconductor layer 104 include amorphous or microcrystalline Si, C, Ge, or their alloys. At the same time, the semiconductor layer 104 desirably contains hydrogen and/or halogen. A desired content thereof is 0.1-40 atom %. The semiconductor layer 104 may further contain impurities of oxygen, nitrogen, or the like. The amount of these impurities is desirably not more than 5×10¹⁹/cm³. Further, the semiconductor layer 104 desirably contains a III-element for a p-type semiconductor, and a V-element for an n-type semiconductor.

In the case where the semiconductor layer 104 is comprised of stacked cells of pin junctions, an i-type semiconductor layer in a pin junction close to the light incidence side preferably has a wide bandgap, and an i-type semiconductor layer in a farther pin junction desirably has a narrower bandgap with distance from the light incidence side. Inside each i-type layer the minimum of the bandgap is desirably located on the p-type layer side with respect to the center of the film thickness.

The doped layer on the light incidence side (the p-type layer or the n-type layer) is preferably made of a crystalline semiconductor with little absorption of light or a semiconductor with a wide bandgap.

A method suitable for formation of the semiconductor layer 104 is microwave (MW) plasma CVD, VHF plasma CVD, or RF plasma CVD.

An example of the semiconductor deposition technology is the technique of forming the i-type layer of Graded SiGe in the Ge content of 20-70 atom % (Japanese Patent Application Laid-Open No. 4-119843).

(Transparent Conductive Layer)

The transparent conductive layer 105 can also serve as an antireflection coating when the film thickness thereof is set at an appropriate value. This transparent conductive layer 105 is formed by forming a film of a material selected from ITO (Indium Tin Oxide), ZnO, Tn₂O₃, and the like by evaporation, CVD, spraying, spin-on, dipping, or the like. These compounds may contain a substance acting to vary the conductivity.

(Collecting Electrodes)

The collecting electrodes 106 are provided for enhancing the electricity collection efficiency. They can be made by one selected from a method of forming a collecting electrode pattern of a metal by sputtering with a mask, a method of printing a conductive paste such as a solder paste, a silver paste, or the like, a method of bonding metal wires with a conductive paste, and so on.

Protective layers can be formed on the both surfaces of the photovoltaic element in certain cases according to necessity. At the same time, a reinforcing member of a steel sheet or the like may also be used in combination.

### EXAMPLES

The present invention will be described below in detail with examples thereof, but it is noted that the present invention is by no means intended to be limited to these examples.

### Experiment Example

First described is Experiment Example in which zinc oxide films were formed under various conditions, using the apparatus shown in FIG. 2.

The conductive substrate (working electrode) 203 was a sheet of stainless steel 430-2D 0.12 mm thick, 50 mm wide, and 50 mm long sputtered with silver in the thickness of 100 nm, and the zinc plate 204 as a counter electrode was a zinc sheet of 4-N (99.99%) 1 mm thick, 50 mm wide, and 50 mm long.

The distance between the back surface of the conductive substrate 203 and a wall surface of the apparatus (made of SiO₂) (the substrate back surface facing distance; numeral 214 in FIG. 2) was set in the range of 3 to 35 mm. The forming bath 202 was a zinc nitrate forming bath at 80° C., and the conductivity was set in the range of 10 to 150 mS/cm. The electric current was allowed to flow in the current density of 3.0 mA/cm² (0.3 A/dm²: 75 mA) between the counter electrode 204 positive and the conductive substrate 203, so as to effect electrolytic deposition.

Film deposition states on the back surface of the conductive substrate 203 as a working electrode (the rounding to the back surface) were checked by visual observation. Further, the resistivity was measured on the back surface of the substrate, which clarified that there was good agreement in the relation between the resistivity on the back surface of the substrate and the back-surface film deposition states (the rounding to the back surface) by visual observation. For this reason, evaluation about the rounding to the back surface was conducted using a relative value of the resistivity on the back surface of the substrate after the formation of the zinc oxide film to that before the formation thereof.

The results of the evaluation about the rounding to the back surface are presented in Table 1. This evaluation was conducted based on the following criteria.

(Criteria)

A: relative value of resistivity of less than 1.2

B: relative value of resistivity of not less than 1.2 and less than 2.0

C: relative value of resistivity of not less than 2.0

D: hard to grow a deposited film on the front surface of the substrate

TABLE 1

| Conductivity | Substrate back surface facing distance (mm) | | | | | | |
|---|---|---|---|---|---|---|---|
| (mS/cm) | 3 | 5 | 10 | 15 | 20 | 30 | 35 |
| 5 | D | D | D | D | D | D | D |
| 10 | B | B | B | B | B | B | C |
| 30 | B | B | B | B | B | B | C |
| 50 | A | A | A | A | B | B | C |
| 80 | A | A | A | A | B | B | C |
| 100 | A | A | A | A | B | B | C |
| 150 | C | C | C | C | C | C | C |

As apparent from Table 1, it was verified that the effect of the present invention was readily achieved in the range of the substrate back surface facing distance of not more than 30 mm and in the range of the conductivity of the solution of 10 to 100 mS/cm and that the effect was prominent, particularly, in the range of the substrate back surface facing distance of not more than 15 mm and in the range of the conductivity of the solution of 50 to 100 mS/cm.

Further, the formation of the zinc oxide film was performed in similar fashion under the above conditions (the substrate back surface facing distance and the conductivity of the zinc nitrate forming bath) and with variation in the current density in the range of 0.01 to 150 mA/cm². As a consequence, there were tendencies that it was hard to form the zinc oxide film in the range of the current density of less than 0.1 mA/cm² and that the rounding to the back surface at the edges increased in the range of the current density of more than 100 mA/cm², but it was verified in the range of the current density of not less than 0.1 mA/cm² nor more than 100 mA/cm² that the effect of the present invention was readily achieved in the range of the substrate back surface facing distance of not more than 30 mm and in the range of the conductivity of the zinc nitrate forming bath of not less than 10 mS/cm nor more than 100 mS/cm and that the effect became more prominent, particularly, in the range of the above distance of not more than 15 mm and in the range of the conductivity of the zinc nitrate forming bath of not less than 30 mS/cm nor more than 100 mS/cm.

### Example 1

In the present example the zinc oxide film was formed using the apparatus shown in FIG. 2. The conductive substrate (working electrode) 203 was a sheet of stainless steel 430-2D 0.12 mm thick, 50 mm wide, and 50 mm long sputtered with silver in the thickness of 100 nm, and the zinc plate 204 as a counter electrode was a zinc sheet of 4-N (99.99%) 1 mm thick, 50 mm wide, and 50 mm long. The distance between the back surface of the conductive substrate 203 and the wall surface of the apparatus (the substrate back surface facing distance; numeral 214 in FIG. 2) was 20 mm. The forming bath 202 was a zinc nitrate forming bath of 80° C. and 0.15 mol/l and the conductivity thereof was set at 50 mS/cm. The electric current was allowed to flow in the current density of 3.0 mA/cm² (0.3 A/dm²:75 mA) between the counter electrode 204 positive and the conductive substrate 203, so as to effect electrolytic deposition.

Film thicknesses were checked by the optical interference method from a wave profile of optical characteristics (V-570 available from JASCO Corporation) of the zinc oxide film obtained on the front surface of the conductive substrate 203 as a working electrode, the number of abnormally grown portions was counted by visual observation (in the range of 3 cm×3 cm), and the number of abnormally grown portions was also counted in the range of 10 mm×10 mm by observation with SEM (S-4500 available from Hitachi, Ltd.). The sample produced was subjected to a bending peel test for each substrate. Further, the resistivity was measured on the back surface of the substrate and the evaluation of the rounding to the back surface was conducted in much the same manner as in Experiment Example. The results thereof are presented in Table 2.

### Example 2

The electrolytic deposition was implemented in much the same manner as in Example 1 except that the forming bath 202 was the zinc nitrate forming bath of the temperature 85° C. and 0.2 mol/l containing 12 g/l of saccharose (the conductivity: 70 mS/cm) and the distance between the back surface of the conductive substrate 203 and the wall surface of the apparatus (the substrate back surface facing distance; numeral 214 in FIG. 2) was 15 mm.

Film thicknesses were checked by the optical interference method from a wave profile of optical characteristics (V-570 available from JASCO Corporation) of the zinc oxide film obtained on the front surface of the conductive substrate 203 as a working electrode, the number of abnormally grown portions was counted by visual observation (in the range of 3 cm×3 cm), and the number of abnormally grown portions was also counted in the range of 10 mm×10 mm by observation with SEM (S-4500 available from Hitachi, Ltd.). The sample produced was subjected to a bending peel test for each substrate. Further, the resistivity was measured on the back surface of the substrate and the evaluation of the rounding to the back surface was conducted in much the same manner as in Experiment Example. The results thereof are presented in Table 2.

### Example 3

The electrolytic deposition was effected in much the same manner as in Example 2 except that the conductive substrate 203 as a working electrode was a sheet of stainless steel 430-2D 0.16 mm thick, 50 mm wide, and 50 mm long sputtered with silver in the thickness of 200 nm and with ZnO in the thickness of 100 nm.

Film thicknesses were checked by the optical interference method from a wave profile of optical characteristics (V-570 available from JASCO Corporation) of the zinc oxide film obtained on the front surface of the conductive substrate 203 as a working electrode, the number of abnormally grown portions was counted by visual observation (in the range of 3 cm×3 cm), and the number of abnormally grown portions was also counted in the range of 10 mm×10 mm by observation with SEM (S-4500 available from Hitachi, Ltd.). The sample produced was subjected to a bending peel test for each substrate. Further, the resistivity was measured on the back surface of the substrate and the evaluation of the rounding to the back surface was conducted in much the same manner as in Experiment Example. The results thereof are presented in Table 2.

### Reference Example 1

The electrolytic deposition was implemented in much the same manner as in Example 1 except that the distance between the back surface of the conductive substrate 203 and the wall surface of the apparatus (the substrate back surface facing distance; numeral 214 in FIG. 2) was 100 mm.

Film thicknesses were checked by the optical interference method from a wave profile of optical characteristics (V-570 available from JASCO Corporation) of the zinc oxide film obtained on the front surface of the conductive substrate 203 as a working electrode, the number of abnormally grown portions was counted by visual observation (in the range of 3 cm×3 cm), and the number of abnormally grown portions was also counted in the range of 10 mm×10 mm by observation with SEM (S-4500 available from Hitachi, Ltd.). The sample produced was subjected to a bending peel test for each substrate. Further, the resistivity was measured on the back surface of the substrate and the evaluation of the rounding to the back surface was conducted in much the same manner as in Experiment Example. The results thereof are presented in Table 2.

TABLE 2

| | Example 1 | Example 2 | Example 3 | Reference 1 |
|---|---|---|---|---|
| Average film | 1200 | 500 | 800 | 1200 |
| thickness (nm) | | | | |
| Rounding to | B | A | A | C |
| back surface | | | | |
| (relative | | | | |
| value) | | | | |
| Number of | 0 | 0 | 0 | 500 |
| abnormally | | | | |
| grown portions | | | | |
| (by visual | | | | |
| observation) | | | | |
| Number or | 30 | 18 | 3 | 1200 |
| abnormally | | | | |
| grown portions | | | | |
| (with SEM) | | | | |
| 180° bending | No peeling; | Neither | Neither | Peeling |
| test | but small | peeling nor | peeling nor | started at |
| | fissures in | fissure | fissure | bent portion, |
| | part | | | and almost |
| | | | | complete |
| | | | | peeling |
| | | | | occurred by |
| | | | | return |

As also seen from the results of Table 2, the rounding to the back surface of the conductive substrate can be prevented by setting the substrate back surface facing distance in the specified range and the conductivity of the electrolytic deposition bath in the specified range (Examples 1 to 3). Further, the abnormal growth of the zinc oxide film can be prevented by adding a saccharide to the electrolytic deposition bath (Example 2). The adhesion between the substrate and the film can be enhanced by preliminarily forming the metal layer on the conductive substrate (Example 3).

### Example 4

A film of silver as a metal layer was deposited in the thickness of 100 nm on a sheet of stainless steel 430-2D of roll shape as a conductive substrate, and a zinc oxide film was deposited in the thickness of 200 nm thereon, using a dc magnetron sputtering apparatus adapted for the roll substrate.

On the zinc oxide film on the conductive substrate, a zinc oxide film was further formed as described below by the roll to roll system shown in FIG. 3.

A support roll (the aforementioned conductive substrate) 303 is fed from a feed roller 301 via a convey roller 304, a zinc oxide layer forming tank 306, and a water wash tank 312 onto a windup roller 302. The zinc oxide layer forming bath contains 70 g of hexa-hydrate salt of zinc nitrate and 0.5 g of dextrin in one liter of water (the conductivity: 90 mS/cm), and a liquid circulation treatment for agitating the interior of the bath is performed. The liquid temperature of the bath 307 is kept at the temperature of 85° C., and pH is kept in the range of 4.0 to 6.0. In the bath 307 there is provided a zinc sheet 120 mm wide and 1500 mm long with a surface thereof buffed, as a counter electrode 305. In the present example, the distance between the support roll 303 and the water surface (the substrate back surface facing distance; numeral 313 in FIG. 3) was set at 10 mm. The electric current was allowed to flow in the current density of 15.0 mA/cm² (1.5 A/dm²: 27000 mA) between the support roll (the width: 120 mm and the length in the solution: 3000 mm) 303 as a working electrode and the counter electrode 305 positive so as to effect electrolytic deposition. In FIG. 3 numeral 308 denotes a power supply, 309 a water wash bath, 310 a drying furnace, and 311 an infrared heater.

The film forming rate was 3 nm/sec, whereby the zinc oxide film was formed in the film thickness of 2000 nm, without deposition of the zinc oxide film on the back surface of the support roll 303.

On the support roll 303 with the zinc oxide film formed as described above, a semiconductor layer of triple cell structure was formed by a CVD system adapted for the roll. An n-type layer was first formed from mixed gas of silane, phosphine, and hydrogen and with supply of RF power of 400 W while heating the metal layer and the zinc oxide layer formed on the support roll 303 as a substrate, at 340° C.; an i-type layer was then formed at the substrate temperature of 450° C., with supply of microwave power, and from mixed gas of silane, germane, and hydrogen; and a p-type layer was further formed at the substrate temperature of 250° C. and from mixed gas of boron trifluoride, silane, and hydrogen, thus forming the bottom pin layers. Subsequently, middle pin layers were also formed in similar procedure with an increased mixing ratio of silane for the i-type layer, and top pin layers were further formed in similar procedure, using silane and hydrogen for the i-type layer. Thereafter, ITO was deposited as a transparent conductive layer by a sputter system adapted for the roll. After that, the collecting electrodes were formed from a silver paste, thus obtaining the photovoltaic element in the structure as shown in FIG. 1.

The optimal operating current and photoelectric conversion efficiency of this element were measured using a solar simulator (AM 1.5, 100 mW/cm², surface temperature 25° C.).

There occurred no conveyance failure (abnormal stop due to a shift of ±3 mm of the edge from a reference value) during 100 m-long film formation in the semiconductor forming apparatus and the transparent electrode forming apparatus adapted for the roll. The results of the above are presented in Table 3, and there arose no problem in the characteristics and others.

### Reference Example 2

The zinc oxide film was formed in much the same manner as in Example 4 except that the distance between the back surface of the conductive substrate 303 and the water surface (the substrate back surface facing distance; numeral 313 in FIG. 3) was 100 mm, and the photovoltaic element was formed similarly.

The optimal operating current and photoelectric conversion efficiency of this element were measured using the solar simulator (AM 1.5, 100 mW/cm², surface temperature 25° C.). As a consequence, there appeared degradation of solar cell characteristics (optimal operating current and photoelectric conversion efficiency) assumed to be due to mixing of gas adsorbing to the back surface film into the vacuum chamber during the formation of the photovoltaic element.

There occurred eighteen conveyance failures (abnormal stops due to the shift of ±3 mm of the edge from the reference value) during 100 m-long film formation in the semiconductor forming apparatus and the transparent electrode forming apparatus adapted to the roll. The results of the above are presented in Table 3 in comparison with the results of Example 4.

TABLE 3

| | Example 4 | Reference 2 |
|---|---|---|
| Optimal operating | 1 | 0.87 |
| current (relative | | |
| comparison with | | |
| Example 4) | | |
| Photoelectric | 1 | 0.87 |
| conversion | | |
| efficiency | | |
| (relative | | |
| comparison with | | |
| Example 4) | | |
| Conveyance failure | null | 18 failures |
| (100 m) | | |

As also seen from the results of Table 3, there occurs no conveyance failure in the roll to roll system and considerable improvement is achieved in the optimal operating current and photoelectric conversion efficiency when the aforementioned factors (1) to (3) are set in the respective specified ranges.

### Example 5

The photovoltaic element was formed in much the same manner as in Example 4, and thereafter a terminal wiring member was provided on the back surface by soldering. The surface was coated with resin to form a surface protective layer.

The optimal operating current and photoelectric conversion efficiency of this element were measured using the solar simulator (AM 1.5, 100 mW/cm², surface temperature 25° C.). Further, this element was subjected to a high-temperature and high-humidity test (a test of keeping the sample in the 85° C. and 85% RH environment for 1000 hours) as an accelerated degrading test, and thereafter change of appearance was observed. The results of the above are presented in Table 4, and there arose no problem in the characteristics and appearance.

### Reference Example 3

The photovoltaic element was formed in much the same manner as in Reference Example 2 and thereafter the terminal wiring member and surface protective layer were formed as in Example 5.

The optimal operating current and photoelectric conversion efficiency of this element were measured using the solar simulator (AM 1.5,. 100 mW/cm², surface temperature 25° C.). Further, this element was subjected to the high-temperature and high-humidity test (the test of keeping the sample in the 85° C. and 85% RH environment for 1000 hours) as an accelerated degrading test, and thereafter change of appearance was observed. The results of the above are presented in Table 4.

In the present example, there occurred defective soldering of the terminal wiring member due to the back surface film and increase of the series resistance lowered the optimal operating current and heavily affected the photoelectric conversion efficiency. There occurred other problems of degradation of adhesion between the resin and the photovoltaic element or film peeling considered to be due to the presence of the back surface film.

TABLE 4

| | Example 5 | Reference 3 |
|---|---|---|
| Optimal operating | 1 | 0.75 |
| current (relative | | |
| comparison with | | |
| Example 5) | | |
| Photoelectric | 1 | 0.75 |
| conversion | | |
| efficiency | | |
| (relative | | |
| comparison with | | |
| Example 5) | | |
| Change in | no change | peeling |
| appearance after HH | | occurred |
| test | | |

As also seen from the results of Table 4, the solar cell module using the photovoltaic element of the present invention is also excellent in the post-processability of soldering, resin coating, and so on.

### Example 6

The zinc oxide film and the photoelectric conversion element were formed and evaluated in much the same manner as in Examples 2 to 5 except that the substrate back surface facing distance, the conductivity of the solution, and the current density in Examples 2 to 5 were varied in various combinations as in Experiment Example, and it was verified, as in Experiment Example, that the effect of the present invention was readily achieved when the distance between the back surface of the working electrode and the counter electrode was in the range of not more than 30 mm, the conductivity of the solution in the range of not less than 10 mS/cm nor more than 100 mS/cm, and the current density in the range of not less than 0.1 mA/cm² nor more than 100 mA/cm².

As described above, the present invention has permitted the zinc oxide film to be formed while reducing the deposition of the film on the back surface of the substrate by electrolytic deposition from the forming bath. When the zinc oxide film forming technique according to the present invention is introduced as a method of forming the back surface reflecting layer into the solar cell production process, it achieves increase in the short-circuit current density and the photoelectric conversion efficiency of the solar cell and improvement in yield characteristics and durability. The material cost, running cost, etc. can be greatly reduced as compared with the sputtering and evaporation, so that the present invention can contribute to widespread use of photovoltaic power generation.

What is claimed is:

1. A method of letting an electric current flow between a conductive substrate immersed in at least one forming bath containing at least zinc ions, and a counter electrode immersed in the at least one forming bath, thereby forming a zinc oxide film on the conductive substrate, wherein deposition of a zinc oxide film on a back surface of the conductive substrate is decreased by adjusting (1) a distance between the back surface of the conductive substrate and a region facing at least the periphery of the back surface in a surface facing the back surface, and (2) an electric conductivity of the forming bath, and (3) an electric current density between the conductive substrate and the counter electrode.

2. The method according to claim 1, wherein the distance is not more than 30 mm, the electric conductivity of the forming bath is not less than 10 mS/cm nor more than 100 mS/cm, and an absolute value of the current density is not less than 0.1 mA/cm² nor more than 100 mA/cm².

3. The method according to claim 1, wherein the back surface of the conductive substrate is not in contact with the surface facing the back surface.

4. The method according to claim 1, wherein the surface facing the back surface of the conductive substrate is comprised of a dielectric.

5. The method according to claim 1, wherein the forming bath contains nitrate ions and further contains a saccharide.

6. The method according to claim 1, wherein the conductive substrate is a conductive substrate having a metal film or a metal compound film deposited thereon.

7. The method according to claim 1, wherein the zinc oxide film is continuously formed by a roll to roll system.

8. A method of producing a semiconductor element substrate having a zinc oxide film on a conductive substrate, which comprises the step of forming a zinc oxide film by the method as set forth in claim 1.

9. A method of producing a photovoltaic element, which comprises the step of forming a semiconductor layer on a semiconductor element substrate produced by the method as set forth in claim 8.
